(19) United States
(12) Patent Application Publication
(10) Pub. No.: US 2012/0326775 A1
(43) Pub. Date: Dec. 27, 2012

(54) CHIP SELECT CIRCUIT AND SEMICONDUCTOR APPARATUS INCLUDING THE SAME

(75) Inventor: Min Ho HEO, Icheon-si (KR)

(73) Assignee: HYNIX SEMICONDUCTOR INC., Icheon-si (KR)

(21) Appl. No.: 13/340,900

(22) Filed: Dec. 30, 2011

(30) Foreign Application Priority Data
Jun. 22, 2011 (KR) 10-2011-0060825

(51) Int. Cl. H01L 25/00

(52) U.S. Cl. 327/564

(57) ABSTRACT

A chip select circuit includes a chip select identification unit, a chip select control unit and a data input unit. The chip select identification unit generates a chip select identification signal in response to a chip select enable signal and an address signal. The chip select control unit provides the chip select identification signal as a chip select signal or provides a signal fixed to a predetermined level as the chip select signal, in response to a test mode signal. The data input unit receives data in response to the chip select signal.

### CROSS-REFERENCES TO RELATED APPLICATION

The present application claims priority under 35 U.S.C. §119(a) to Korean application number 10-2011-0060825, filed on Jun. 22, 2011, in the Korean Intellectual Property Office, which is incorporated herein by reference in its entirety.

### BACKGROUND

1. Technical Field

The present invention relates generally to a semiconductor apparatus, and more particularly to a chip select circuit for selecting a desired one of a plurality of chips constituting a semiconductor is apparatus.

2. Related Art

With increasing demand for large-capacity semiconductor devices, a stack type semiconductor package manufactured by stacking a plurality of semiconductor chips is being developed. Particularly, a semiconductor memory apparatus such as a DRAM or flash memory forms a single semiconductor apparatus by stacking a plurality of such chips so as to increase its storage capacity.

Unlike a semiconductor apparatus including a single semiconductor chip, the stack type semiconductor apparatus should select one or more of a plurality of chips and operate the selected chip. Therefore, the stack type semiconductor apparatus includes a chip select circuit capable of selecting a chip to be operated.

FIGS. 1A and 1B illustrate a chip select method when a plurality of chips constitute a single semiconductor apparatus. When four chips Chip1 to Chip4 are stacked to constitute a single semiconductor apparatus, a method of individually selecting the four chips Chip1 to Chip4 is illustrated in FIGS. 1A and 1B. In FIG. 1, two or more chip select enable signals CE1 and CE2 are required to individually select the four chips Chip1 to Chip4. The four chips Chip1 to Chip4 commonly receive the two chip select enable signals CE1 and CE2, and a chip to be selected can be determined based on levels of the two chip select enable signals CE1 and CE2. For example, if the first chip select enable signal CE1 has a low level and the second chip select enable signal CE2 has a low level, a first chip select signal is generated so that the first chip Chip1 can be selected. If the first chip select enable signal CE1 has a high level and the second chip select enable signal CE2 has a low level, a third chip select signal is generated so that the third chip Chip3 can be selected.

As such, two chip select enable signals are required to individually select four chips. Generally, a semiconductor apparatus has a plurality of chip select pins for communicating with an external system, and the chip select enable signals are received through the chip select pins. The chip select pins occupy a large part of the area of the semiconductor apparatus or package, and thus by decreasing the number of the chip select pins, the size of the semiconductor apparatus or package can be reduced. Although it has been illustrated in FIG. 1 that the four chips are stacked, three or more chip select enable signals are required when eight or more chips are stacked, and the number of chip select pins is inevitably increased so as to receive the chip select signals. Therefore, it is considerably disadvantageous for miniaturization and integration of the semiconductor apparatus.

To reduce the required chip select enable signal, an address signal terminal may be used as a terminal for the chip select enable signals. As illustrated in FIG. 1B, the first to fourth chips Chip1 to Chip4 commonly receive a chip select enable signal CE1 and an address signal ADD, and a desired chip can be selected based on levels of the chip select enable signal CE1 and the address signal ADD.

However, if a test is performed by using the chip select methods described above, the test cannot be simultaneously performed on all the chips constituting the semiconductor apparatus. That is, since only a specific chip is activated in response to the chip select enable signal or the address signal, it is impossible to simultaneously perform the test on all the chips. Accordingly, the test time of the semiconductor apparatus increases in proportion to the number of stacked chips.

### SUMMARY

A chip select circuit of a semiconductor apparatus, which can simultaneously select all chips in a test operation, is described herein.

In one embodiment of the present invention, a chip select circuit includes a chip select identification unit configured to generate a chip select identification signal in response to a chip select enable signal and an address signal, a chip select control unit configured to provide the chip select identification signal as a chip select signal or provide a signal fixed to a predetermined level as the chip select signal, in response to a test mode signal, and a data input unit configured to receive data in response to the chip select signal.

In another embodiment of the present invention, a semiconductor apparatus includes a first chip select unit configured to be disposed in a first chip and generate a first chip select signal in response to a chip select enable signal and an address signal, and a second chip select unit configured to be disposed in a second chip stacked together with the first chip and generate a second chip select signal in response to the chip select enable signal and the address signal. In the semiconductor apparatus, the first and second chip select units enable the respective first and second chip select signals regardless of the address signal in a test operation.

In still another embodiment of the present invention, a semiconductor apparatus includes first and second chips communicating with a controller through a command channel and an address channel. The semiconductor apparatus includes a first chip select unit configured to be disposed in the first chip and generate a first chip selection signal in response to a signal inputted through the command channel and a signal inputted through the address channel, and a second chip select unit configured to be disposed in the second chip and generate a second chip select signal in response to the signal inputted through the command channel and the signal inputted through the address channel, wherein. In the semiconductor apparatus, when a signal for instructing a test operation is inputted through the command channel, the first and second chip select units enable the respective first and second chip select signals regardless of the signal inputted through the address signal.

### BRIEF DESCRIPTION OF THE DRAWINGS

Features, aspects, and embodiments are described in conjunction with the attached drawings, in which:

FIG. 1A is a table illustrating a method of individually selecting four chips using two chip select enable signals;

FIG. 1B is a table illustrating a method of individually selecting four chips using one chip select enable signal and one address signal;

FIG. 2 is a diagram schematically illustrating a configuration of a semiconductor apparatus according to an embodiment of the present invention; and

FIG. 3 is a block diagram illustrating a configuration of a first chip select unit of FIG. 2 and a data input unit for allowing a first chip to be activated by a first chip select signal.

### DETAILED DESCRIPTION

Hereinafter, a chip select circuit and a semiconductor apparatus including the same according to the present invention will be described below with reference to the accompanying drawings through exemplary embodiments.

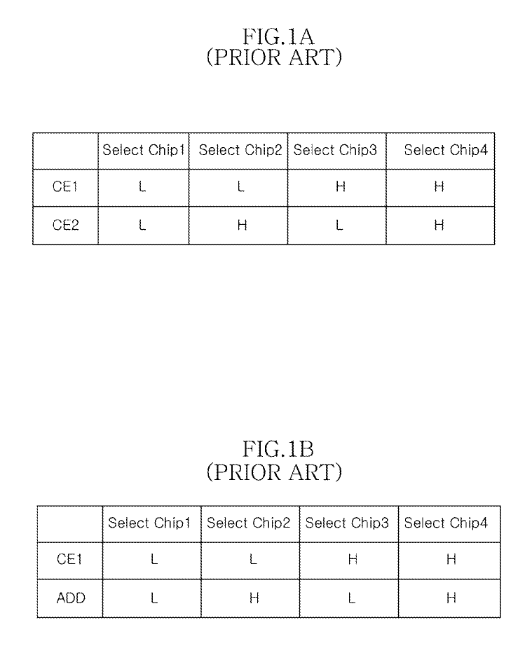

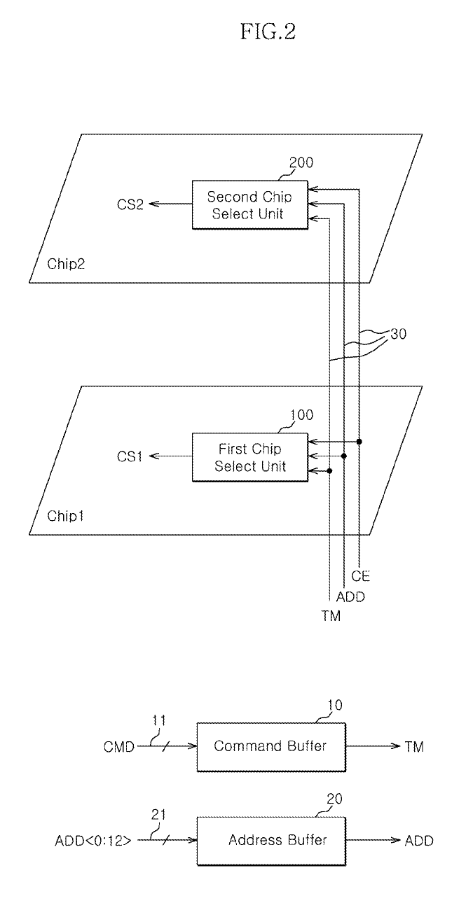

FIG. 2 is a diagram schematically illustrating a configuration of a semiconductor apparatus according to an embodiment of the present invention. In FIG. 2, the semiconductor apparatus includes first and second chips Chip 1 and Chip2. The first and second chips Chip 1 and Chip2 constitute a single semiconductor apparatus by being stacked and packaged as the single semiconductor apparatus. Although it has been illustrated in FIG. 1 that the number of the stacked chips is two, the present invention is not limited thereto. That is, a case where a larger number of chips are stacked can also be applied to the scope of the present invention.

In FIG. 2, the first chip Chip1 includes a first chip select unit 100, and the second chip Chip2 includes a second chip select unit 200. The first chip select unit 100 generates a first chip select signal CS1 in response to a chip select enable signal CE and an address signal ADD. The second chip select unit 200 generates a second chip select signal CS2 in response to the chip select enable signal CE and the address signal ADD.

When the chip select enable signal CE has a first level and the address signal ADD has the first level, the first chip select unit 100 enables the first chip select signal CS1. In other cases, the first chip select unit 100 disables the first chip select signal CS1. When the chip select enable signal CE has the first level and the address signal ADD has a second level, the second chip select unit 200 enables the second chip select signal CS2. In other cases, the second chip select unit 200 disables the second chip select signal CS2. In an embodiment of the present invention, the first level may be a logic high level, and the second level may be a logic low level.

When a test operation of the semiconductor apparatus is performed, the first and second chip select units 100 and 200 enable the respective first and second chip select signals CS1 and CS2 regardless of the level of the address signal ADD. The first and second chip select units 100 and 200 enable the respective first and second chip select signals CS1 and CS2 in response to a test mode signal TM for instructing the test operation. Thus, when the semiconductor apparatus performs the test operation, the first and second chip select units 100 and 200 enable the respective first and second chip select signals CS1 and CS2 regardless of the level of the address signal ADD, and allow the respective first and second chips Chip1 and Chip2 to be activated and operated. On the other hand, when the semiconductor apparatus does not perform the test operation but performs a normal operation, the first and second chip select units 100 and 200 enable one of the first and second chip select signals CS1 and CS2, and allow one of the first and second chips Chip1 and Chip2 to be selectively activated.

In addition, the semiconductor apparatus can further include a command buffer 10 and an address buffer 20. The command buffer 10 receives a plurality of command signals CMD from an external controller (not shown) through a command channel 11. The command buffer 10 enables the test mode signal TM when the plurality of command signals CMD form a predetermined combination. The chip select enable signal CE may also be received through the command channel 11. Thus, the test mode signal TM and the chip select enable signal CE may be inputted through the command channel 11.

The address buffer 20 receives a plurality of address signals ADD<0:12> from the external controller through an address channel 21. The address buffer 20 can provide, as the address signal ADD, one of the plurality of address signals ADD<0:12>, which does not serve as the address signal in the test operation. For example, a most-significant-bit signal among the plurality of address signals ADD<0:12> can be provided as the address signal ADD.

The command buffer 10 and the address buffer 20 can be arranged in one or both of the first and second chips Chip1 and Chip2. Alternatively, the command buffer 10 and the address buffer 20 can be arranged in another chip (e.g., a master chip (not shown), but the present invention is not limited thereto) except the first and second chips Chip1 and Chip2. The test mode signal TM, the address signal ADD and the chip select enable signal CE can be transmitted to each of the first and second chips Chip1 and Chip2 through any signal transmission channel 30 used in the stack type semiconductor apparatus, such as a wire or through via.

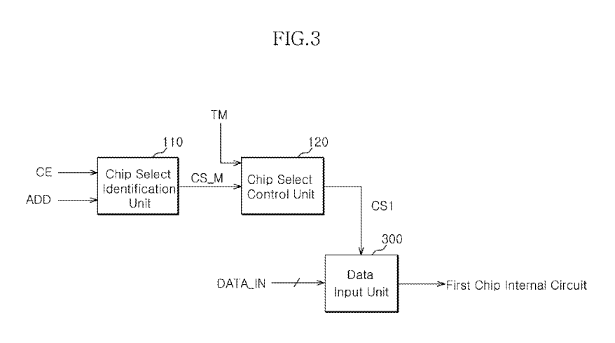

FIG. 3 illustrates a configuration of a data input unit 500 for allowing the first chip Chip1 to be activated by the first chip select signal CS1. Each of the second chip select unit 200 of the second chip Chip2 and a data input unit can have a configuration identical to that illustrated in FIG. 3.

In FIG. 3, the first chip select unit 100 includes a chip select identification unit 110 and a chip select control unit 120. The chip select identification unit 110 receives the chip select enable signal CE and the address signal ADD and generates a chip select identification signal CS_M. When the chip select enable signal CE has the first level and the address signal ADD has the first level, for example, the chip select identification unit 110 enables the chip select identification signal CS_M. When the chip select enable signal CE has the first level and the address signal ADD has the second level, for example, the chip select identification unit 110 disables the chip select identification signal CS_M.

The chip select control unit 120 receives the chip select identification signal CS_M, and provides the chip select identification signal CS_M as the first chip select signal CS1 or provides a signal fixed to a predetermined voltage level as the first chip select signal CS1, in response to the test mode signal TM. The predetermined voltage level may be a voltage level of an enabled first chip select signal CS1 which can activate the first chip Chip1. Thus, when the signal fixed to the predetermined voltage level is provided, the first chip select signal CS1 is enabled. When the test mode signal TM is enabled, the chip select control unit 120 provides the signal fixed to the predetermined voltage level as the first chip select signal CS1 so that the first chip select signal CS1 is enabled. When the test mode signal TM is disabled, the chip select control unit 120 provides the chip select identification signal CS_M as the first chip select signal CS1. Thus, when the test mode signal TM is disabled, the chip select control unit 120 enables or disables the first chip select signal CS1 based on the chip select identification signal CS_M.

The data input unit 300 transmits input data DATA_IN to a first chip internal circuit in response to the first chip select signal CS1. If the first chip select signal CS1 is enabled so that the first chip Chip1 is activated, the data input unit 300 transmits the input data DATA_IN to the first chip internal circuit. If the first chip select signal CS1 is disabled so that the first chip Chip1 is not activated, the data input unit 300 would not allow the input data DATA_IN to be transmitted to the first chip internal circuit. The input data DATA_IN may be a signal outputted from a data receiver (not shown) for receiving data inputted from the external controller.

A chip select method according to an embodiment of the present invention will be described with reference to FIGS. 2 and 3. First, in the normal operation of the semiconductor apparatus, the test mode signal TM is disabled. If the chip select enable signal CE inputted through the command channel is enabled, one of the first and second chips Chip1 and Chip2 would activated for performing the normal operation. If the address signal ADD inputted through the address channel 21 has the first level, the first chip Chip1 is selected to perform the normal operation. On the contrary, if the address signal ADD has the second level, the second chip Chip2 is selected to perform the normal operation.

In the test operation of the semiconductor apparatus, the test mode signal TM is enabled in response to the plurality of command signals CMD inputted through the command channel 11. If the chip select enable signal CE is enabled, the first and second chips Chip1 and Chip2 can perform the test operation. In this case, only one of the first and second chips Chip1 and Chip2 is selected based on the level of the address signal ADD. However, in an embodiment of the present invention, the semiconductor apparatus has the chip select control unit 120, so that both the first and second chip select signals CS1 and CS2 can be enabled regardless of the level of the address signal ADD. Thus, all the chips can be activated regardless of the level of the address signal inputted to individually select a chip in the test operation. Accordingly, the test operation is simultaneously performed on all the chips, and the test time of the semiconductor apparatus may decrease.

While certain embodiments have been described above, it will be understood to those skilled in the art that the embodiments described are by way of example only. Accordingly, the chip select circuit and the semiconductor apparatus including the same described herein should not be limited based on the described embodiments. Rather, the chip select circuit and the semiconductor apparatus including the same described herein should only be limited in light of the claims that follow when taken in conjunction with the above description and accompanying drawings.

What is claimed is:

1. A chip select circuit, comprising:
a chip select identification unit configured to generate a chip select identification signal in response to a chip select enable signal and an address signal;
a chip select control unit configured to provide the chip select identification signal as a chip select signal or provide a signal fixed to a predetermined level as the chip select signal, in response to a test mode signal; and
a data input unit configured to receive data in response to the chip select signal.

2. The chip select circuit according to claim 1, wherein the chip select identification unit enables the chip select identification signal when the chip select enable signal and the address signal have a predetermined combination.

3. The chip select circuit according to claim 1, wherein the chip select control unit provides the chip select identification signal as the chip select signal when the test mode signal is disabled, and provides the signal fixed to the predetermined level as the chip select signal when the test mode signal is enabled.

4. The chip select circuit according to claim 1, wherein the signal fixed to the predetermined level allows the chip select signal to be enabled.

5. The chip select circuit according to claim 1, wherein the data input unit receives the data when the chip select signal is enabled.

6. The chip select circuit according to claim 1, further comprising a command buffer configured to generate the test mode signal by combining a plurality of command signals transmitted through a command channel from a controller.

7. The chip select circuit according to claim 1, wherein the address signal uses one of a plurality of address signals received from the controller through an address channel, which does not serve as the address signal in a test operation.

8. A semiconductor apparatus comprising:
a first chip select unit configured to be arranged in a first chip and generate a first chip select signal in response to a chip select enable signal and an address signal; and
a second chip select unit configured to be arranged in a second chip and generate a second chip select signal in response to the chip select enable signal and the address signal,
wherein the first and second chip select units enable the respective first and second chip select signals regardless of the address signal in a test operation.

9. The semiconductor apparatus according to claim 8, wherein the first and second chip form a single stack type package.

10. The semiconductor apparatus according to claim 8, wherein the first chip select unit enables the first chip select signal when the chip select signal has a first level and the address signal has the first level, and the second chip select unit enables the second chip select signal when the chip select signal has the first level and the address signal has a second level.

11. The semiconductor apparatus according to claim 10, wherein the first and second chip select units enable the respective first and second chip signals regardless of a level of the address signal in the test operation.

12. The chip select circuit according to claim 8, further comprising a command buffer configured to transmit a test mode signal to the first and second chip select units.

13. A semiconductor apparatus including first and second chips communicating with a controller through a command channel and an address channel, the semiconductor apparatus comprising:
a first chip select unit configured to be arranged in the first chip and generate a first chip selection signal in response to a signal inputted through the command channel and a signal inputted through the address channel; and
a second chip select unit configured to be arranged in the second chip and generate a second chip select signal in response to the signal inputted through the command channel and the signal inputted through the address channel,
wherein, when a signal for instructing a test operation is inputted through the command channel, the first and second chip select units enable the respective first and second chip select signals regardless of the signal inputted through the address signal.
